(19) United States
(12) Patent Application Publication
(10) Pub. No.: US 2025/0062302 A1
(43) Pub. Date: Feb. 20, 2025

(54) SEMICONDUCTOR PACKAGE

(71) Applicant: SAMSUNG ELECTRONICS CO., LTD., Suwon-si (KR)

(72) Inventor: Junghoon KANG, Suwon-si (KR)

(73) Assignee: SAMSUNG ELECTRONICS CO., LTD., Suwon-si (KR)

(21) Appl. No.: 18/605,431

(22) Filed: Mar. 14, 2024

(30) Foreign Application Priority Data
Aug. 16, 2023 (KR) 10-2023-0106757

(51) Int. Cl. H01L 25/18; H01L 23/00; H01L 23/29; H01L 23/31; H01L 23/48; H01L 23/498

(52) U.S. Cl. CPC H01L 25/18; H01L 23/295; H01L 23/3128; H01L 23/481; H01L 23/49833; H01L 24/08; H01L 24/16; H01L 24/32; H01L 24/73; H01L 2224/08225; H01L 2224/16238; H01L 2224/32225; H01L 2224/73204; H01L 2924/1011; H01L 2924/1431; H01L 2924/1436; H01L 2924/181

(57) ABSTRACT

A semiconductor package includes a lower redistribution substrate, a logic structure on the lower redistribution substrate, connection terminals between the lower redistribution substrate and the logic structure, connection structures on the lower redistribution substrate and surrounding the logic structure in plan view, and external connection terminals below the lower redistribution substrate. The logic structure includes a first redistribution substrate, a connection substrate on the first redistribution substrate and having an opening in the connection substrate, a first logic chip on the first redistribution substrate and in the opening in the connection substrate, and a second logic chip on the connection substrate and the first logic chip. A first active surface of the first logic chip faces a second active surface of the second logic chip.

### CROSS-REFERENCE TO RELATED APPLICATION

This U.S. nonprovisional application claims priority under 35 U.S.C § 119 to Korean Patent Application No. 10-2023-0106757 filed on Aug. 16, 2023 in the Korean Intellectual Property Office, the disclosure of which being hereby incorporated by reference in its entirety.

### BACKGROUND

Apparatuses and devices consistent with the present disclosure relate to a semiconductor package, and more particularly, to a semiconductor package with improved electrical properties and increased reliability.

In the semiconductor industry, there is demand for high capacity, thinness, and small size of semiconductor devices and electronic products using the same and thus various package techniques have been suggested. A semiconductor package is provided to implement an integrated circuit chip to qualify for use in electronic products. A semiconductor package is typically configured such that a semiconductor chip is mounted on a printed circuit board (PCB) and bonding wires or bumps are used to electrically connect the semiconductor chip to the printed circuit board. With the development of the electronic industry, the demand for electronic products having increasingly high performance, high speed, and compact size has increased.

### SUMMARY

It is an aspect to provide a semiconductor package with improved electrical properties and increased structural stability.

It is another aspect to provide a method of fabricating a semiconductor package whose fabrication process is simplified and whose cost is reduced and a semiconductor package fabricated by the same.

According to an aspect of some embodiments, there is provided a semiconductor package comprising a lower redistribution substrate; a logic structure on the lower redistribution substrate; a plurality of connection terminals between the lower redistribution substrate and the logic structure; a plurality of connection structures on the lower redistribution substrate, the plurality of connection structures surrounding the logic structure in plan view; and a plurality of external connection terminals below the lower redistribution substrate. The logic structure includes a first redistribution substrate; a connection substrate on the first redistribution substrate, the connection substrate having an opening in the connection substrate; a first logic chip on the first redistribution substrate and in the opening in the connection substrate; and a second logic chip on the connection substrate and the first logic chip. A first active surface of the first logic chip faces a second active surface of the second logic chip.

According to another aspect of some embodiments, there is provided a semiconductor package comprising a first redistribution substrate; a connection substrate on the first redistribution substrate, the connection substrate having an opening in the connection substrate; a first logic chip on the first redistribution substrate and in the opening of the connection substrate; a first molding layer that covers the connection substrate and the first logic chip; a dielectric pattern on the first molding layer; and a second logic chip on the dielectric pattern. The first molding layer extends into a gap between the connection substrate and the first logic chip and includes a resin material containing a filler.

According to yet another aspect of some embodiments, there is provided a semiconductor package comprising a first redistribution substrate that includes a redistribution line and a redistribution via; a connection substrate on the first redistribution substrate, the connection substrate having an opening that includes a connection via; a first logic chip in the opening in the connection substrate, the first logic chip including a through via; and a second logic chip on the first logic chip. A width of the redistribution via decreases with an increasing distance from a bottom surface of the first redistribution substrate, a width of the connection via increases with the increasing distance from the bottom surface of the first redistribution substrate, and a size in a first direction of the first logic chip is less than a size in the first direction of the second logic chip.

### BRIEF DESCRIPTION OF DRAWINGS

The above and other aspects will be described below with reference to the drawings, in which:

FIG. 1 illustrates a cross-sectional view showing a semiconductor package according to some embodiments;

FIG. 2 illustrates an enlarged view showing section P of FIG. 1;

FIG. 3 illustrates a cross-sectional view showing a semiconductor package according to some embodiments;

FIG. 4 illustrates a cross-sectional view showing a semiconductor package according to some embodiments;

FIG. 5 illustrates a plan view showing a semiconductor package according to some embodiments;

FIGS. 6A and 6B illustrate cross-sectional views taken along line A-A′ of FIG. 5, showing a semiconductor package according to some embodiments;

FIGS. 7 to 12 illustrate cross-sectional views showing a method of fabricating a semiconductor package according to some embodiments.

### DETAILED DESCRIPTION

The aspects are not limited to those aspects mentioned above, and other aspects which have not been mentioned above will be clearly understood to those skilled in the art from the following description.

The following will now describe various embodiments with reference to the accompanying drawings. Like reference numerals may indicate like components throughout the description and repeated description thereof may be omitted in some instances to avoid redundancy and for conciseness.

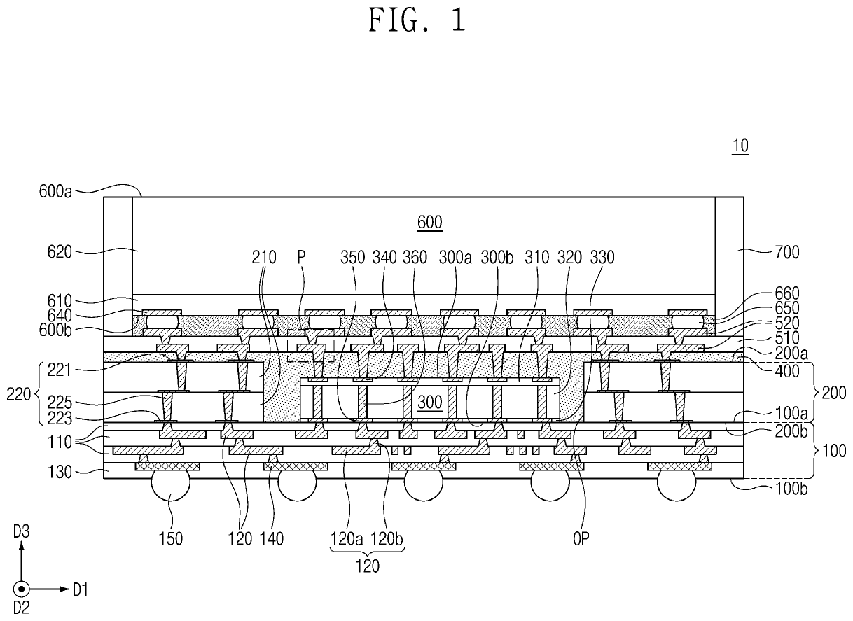

FIG. 1 illustrates a cross-sectional view showing a semiconductor package according to some embodiments.

Referring to FIG. 1, a first redistribution substrate 100 may be provided. The first redistribution substrate 100 may include a plurality of first dielectric patterns 110, a substrate protection layer 130, and a plurality of first conductive patterns 120. The first redistribution substrate 100 may have a bottom surface 100b and a top surface 100a opposite to the bottom surface 100b. The top surface 100a of the first redistribution substrate 100 may be located at a higher level than a level of the bottom surface 100b of the first redistribution substrate 100.

The plurality of first dielectric patterns 110 may be stacked in a vertical direction (e.g., a third direction D3). An uppermost one of the first dielectric patterns 110 may have a thickness that is less than thicknesses of the other first dielectric patterns 110, but embodiments are not limited thereto. For example, in some embodiments, each of the first dielectric patterns 110 may have substantially the same thickness. A top surface of the uppermost one of the first dielectric patterns 110 may correspond to the top surface 100a of the first redistribution substrate 100.

The plurality of first dielectric patterns 110 may include a polymer. For example, the first dielectric patterns 110 may include a dielectric polymer and/or a photo-imageable dielectric (PID). The photo-imageable dielectric may include at least one selected from photosensitive polyimide, polybenzoxazole (PBO), phenolic polymers, and benzocyclobutene polymers. In some embodiments, the first dielectric patterns 110 may include a dielectric material. For example, the first dielectric patterns 110 may include silicon oxide (SiO), silicon nitride (SiN), silicon oxynitride (SiON), and/or a dielectric polymer.

The plurality of first conductive patterns 120 may be positioned in the plurality of first dielectric patterns 110. For example, the plurality of first conductive patterns 120 may be correspondingly positioned on bottom surfaces of the plurality of first dielectric patterns 110. The first conductive patterns 120 may be wiring lines of the first redistribution substrate 100 or parts that connect the wiring lines to each other. For example, the first conductive patterns 120 may be components for horizontal redistribution in the first redistribution substrate 100. The first conductive patterns 120 may include a conductive material. For example, the first conductive patterns 120 may include metal such as copper (Cu).

The plurality of first conductive patterns 120 each may have a damascene structure. For example, each of the first conductive patterns 120 may include a first line 120a and a first via 120b. The first line 120a may extend in a horizontal direction while being positioned on the bottom surface of the first dielectric pattern 110. The first via 120b may protrude in the third direction D3 from the first line 120a and may penetrate a portion of the first dielectric pattern 110. In some embodiments, each of the plurality of first conductive patterns 120 may have an inverse T shape.

In some embodiments, the first via 120b may be a component for vertically connecting neighboring first lines 120a. In some embodiments, the first via 120b may be a component for connecting the first redistribution substrate 100 to a connection substrate 200 or a first logic chip 300 which will be discussed below. In this latter connection, the first via 120b may be coupled to a lower pad 223 of the connection substrate 200 or to a backside pad 350 of a first logic chip 300. The first via 120b may have different widths between a top surface and a bottom surface thereof. For example, a width in a first direction D1 or a second direction D2 of the first via 120b may decrease in a direction from the bottom surface 100b to the top surface 100a of the first redistribution substrate 100. In such a case, the first via 120b may have a width that decreases in the third direction D3 from the bottom surface 100b to the top surface 100a of the first redistribution substrate 100.

A plurality of connection terminal pads 140 may be provided on a bottom surface of a lowermost one of the first dielectric patterns 110. The plurality of connection terminal pads 140 may be connected to the first vias 120b of a lowermost one of the first conductive patterns 120. The plurality of connection terminal pads 140 may be connected to a plurality of connection terminals 150 which will be discussed below.

The substrate protection layer 130 may be provided on the bottom surface of the lowermost one of the first dielectric patterns 110. The substrate protection layer 130 may cover the plurality of connection terminal pads 140. In some embodiments, the substrate protection layer 130 may outwardly expose the plurality of connection terminal pads 140. In this embodiment, the substrate protection layer 130 may cover the bottom surface of the lowermost one of the plurality of first dielectric patterns 110, and may not cover bottom surfaces of the plurality of connection terminal pads 140. For example, the substrate protection layer 130 may include a dielectric polymer and/or a photo-imageable dielectric (PID).

The plurality of connection terminal pads 140 may be provided with the plurality of connection terminals 150 on the bottom surfaces of the plurality of connection terminal pads 140, respectively. The connection terminals 150 may penetrate a portion of the substrate protection layer 130 to come into connection with the connection terminal pads 140. For example, the connection terminals 150 may include solder balls or solder bumps. Based on a type and arrangement of the connection terminals 150, a semiconductor package may be provided in the form of a ball grid array (BGA) type, a fine ball-grid array (FBGA) type, or a land grid array (LGA) type, etc.

A connection substrate 200 may be provided on the first redistribution substrate 100. The connection substrate 200 may have an opening OP that penetrates through the connection substrate 200. For example, the opening OP may be shaped like an open hole that connects to each other a top surface 200a and a bottom surface 200b of the connection substrate 200. In other words, a sidewall of the opening OP may connect the top surface 200a to the bottom surface 200b of the connection substrate 200. The opening OP may be defined to refer to a space in which is disposed a first logic chip 300 which will be discussed below. The bottom surface 200b of the connection substrate 200 may be in contact with the top surface 100a of the first redistribution substrate 100. For example, the first logic chip 300 may be provided as a fan-out panel level package (FO-PLP).

The connection substrate 200 may include a base layer 210 and a conductive member 220 that is a line pattern provided in the base layer 210. In some embodiments, the base layer 210 may be provided in plural. In the example illustrated in FIG. 1, the base layer 210 is provided as two base layers. However, embodiments are not limited thereto. In some embodiments, an uppermost one of the base layers 210 may have a top surface that corresponds to the top surface 200a of the connection substrate 200, and a lowermost one of the base layers 210 may have a bottom surface that corresponds to the bottom surface 200b of the connection substrate 200.

The conductive member 220 may be disposed between the opening OP and an outer lateral surface of the connection substrate 200. The conductive member 220 may include a plurality of upper pads 221, a plurality of lower pads 223, and a plurality of connection vias 225. In some embodiments, the upper pads 221 may be disposed on the top surface of the uppermost one of the base layers 210, but embodiments are not limited thereto. For example, in some embodiments, the upper pads 221 may be buried in the uppermost one of the base layers 210, and top surfaces of the upper pads 221 may be coplanar with the top surface 200a of the connection substrate 200. In some embodiments, the lower pads 223 may be disposed on the bottom surface of the lowermost one of the base layers 210, but embodiments are not limited thereto. For example, in some embodiments, the lower pads 223 may be buried in the lowermost one of the base layers 210, and bottom surfaces of the lower pads 223 may be coplanar with the bottom surface 200b of the connection substrate 200.

The plurality of connection vias 225 may penetrate the base layers 210 to electrically connect the upper pads 221 to the lower pads 223. Each of the connection vias 225 may have different widths between a top surface and a bottom surface of the connection via 225. For example, the connection vias 225 may each have widths in the first direction D1 and the second direction D2, and the widths may increase in a direction from the bottom surface 200b of the connection substrate 200 to the top surface 200a of the connection substrate 200. In this sense, each of the connection vias 225 may have a width that increases in the third direction D3 from the bottom surface 200b of the connection substrate 200 to the top surface 200a of the connection substrate 200.

The base layer 210 may include at least one selected from a dielectric polymer, a photo-imageable dielectric (PID), and a dielectric material. For example, the upper pads 221, the lower pads 223, and the connection vias 225 may include a conductor or metal, such as copper (Cu).

The connection substrate 200 may be mounted on the first redistribution substrate 100. For example, the connection substrate 200 may be in contact with and electrically connected to the first redistribution substrate 100. The first vias 120b of the uppermost ones of the first conductive patterns 120 may penetrate the uppermost one of the first dielectric patterns 110 to come into connection with the lower pads 223 of the connection substrate 200. Therefore, the connection substrate 200 may be electrically connected through the first redistribution substrate 100 to the connection terminals 150.

The first logic chip 300 may be provided on the first redistribution substrate 100 and positioned in the opening OP of the connection substrate 200. The first logic chip 300 may be in contact with the top surface 100a of the first redistribution substrate 100 that is exposed by the opening OP. In some embodiments, the first logic chip 300 may fill a portion of the opening OP. In some embodiments, a bottom surface 300b of the first logic chip 300 may be coplanar with the bottom surface 200b of the connection substrate 200. In some embodiments, the bottom surface 300b of the first logic chip 300 may be coplanar with the top surface 100a of the first redistribution substrate 100. In some embodiments, a top surface 300a of the first logic chip 300 may be located at a lower level than a level of the top surface 200a of the connection substrate 200. In some embodiments, the first logic chip 300 may have a height that is less than a height of the connection substrate 200, but embodiments are not limited thereto. In some embodiments, the first logic chip 300 may include an application specific integrated circuit (ASIC) chip or an application processor (AP) chip. In some embodiments, the first logic chip 300 may include a central processing unit (CPU) or a graphic processing unit (GPU). The ASIC chip may include an application specific integrated circuit (ASIC).

The first logic chip 300 may include a first circuit layer 310, a first protection layer 330, and a first semiconductor layer 320. The first circuit layer 310 may be positioned on the first semiconductor layer 320, and the first protection layer 330 may be positioned on the first semiconductor layer 320. For example, in some embodiments, the first circuit layer 310 may be positioned on a top surface of the first semiconductor layer 320 and the first protection layer 330 may be positioned on a bottom surface of the first semiconductor layer 320. A top surface of the first circuit layer 310 may correspond to the top surface 300a of the first logic chip 300. A bottom surface of the first protection layer 330 may correspond to the bottom surface 300b of the first logic chip 300.

The first circuit layer 310 may include a plurality of front pads 340, an integrated circuit, and a dielectric material. The plurality of front pads 340 may be positioned on the top surface of the first circuit layer 310. The integrated circuit may be a logic circuit. The integrated circuit may be constituted by an electronic element such as a transistor, a dielectric pattern, and wiring patterns. The dielectric material may expose the plurality of front pads 340 on the top surface of the first circuit layer 310, while covering the integrated circuit. For example, top surfaces of the plurality of front pads 340 may be coplanar with the top surface 300a of the first logic chip 300. The plurality of front pads 340 may be connected through the integrated circuit to a plurality of through vias 360 which will be discussed below. The plurality of front pads 340 may be in contact with lowermost ones of a plurality of second conductive patterns 520 which will be discussed below.

The first protection layer 330 may include a plurality of backside pads 350 and a dielectric material. The plurality of backside pads 350 may be positioned on a bottom surface of the first protection layer 330. The dielectric material may expose the plurality of backside pads 350 on the bottom surface of the first protection layer 330, while covering lateral surfaces of the backside pads 350. For example, bottom surfaces of the plurality of backside pads 350 may be coplanar with the bottom surface 300b of the first logic chip 300. For example, the plurality of front pads 340 and the plurality of backside pads 350 may include various metallic materials, such as one or more of copper (Cu), aluminum (Al), and nickel (Ni).

The first semiconductor layer 320 may include the plurality of through vias 360 in the first semiconductor layer 320. The plurality of through vias 360 may be in contact with the plurality of backside pads 350, and may be electrically connected to the plurality of front pads 340 through the integrated circuit of the first circuit layer 310. For example, the plurality of through vias 360 may electrically connect the plurality of front pads 340 to the plurality of backside pads 350.

In the first logic chip 300, the top surface of the first circuit layer 310 including the integrated circuit thereon may be a first active surface of the first logic chip 300. The bottom surface of the first protection layer 330 including no integrated circuit thereon may be a first inactive surface of the first logic chip 300. For example, the top surface 300a of the first logic chip 300 may correspond to the first active surface of the first logic chip 300, and the bottom surface 300b of the first logic chip 300 may correspond to the first inactive surface of the first logic chip 300. Since the first active surface of the first logic chip 300 is located at a higher level than a level of the first inactive surface of the first logic chip 300, the first logic chip 300 may be provided in a face-up position.

A direct bonding method may be used to mount the first logic chip 300 on the first redistribution substrate 100. For example, the bottom surface 300b of the first logic chip 300 may be in contact with the top surface 100a of the first redistribution substrate 100. The plurality of backside pads 350 may be connected to the uppermost ones of the plurality of first conductive patterns 120. Thus, the first logic chip 300 may be electrically connected to the first redistribution substrate 100. The first logic chip 300 may be electrically connected through the first redistribution substrate 100 to the plurality of connection terminals 150. Therefore, solder balls or solder bumps may be omitted between the first logic chip 300 and the first redistribution substrate 100, and accordingly a semiconductor package 10 may become small in size.

A first molding layer 400 may be provided on the connection substrate 200. The first molding layer 400 may cover the connection substrate 200 and the first logic chip 300. The first molding layer 400 may fill an unoccupied portion of the opening OP in the connection substrate 200. The first molding layer 400 may extend into a gap between the connection substrate 200 and the first logic chip 300 to reside between the connection substrate 200 and the first logic chip 300. Since the first molding layer 400 covers the top surface 200a of the connection substrate 200 and the top surface 300a of the first logic chip 300, a top surface of the first molding layer 400 may be located at a higher level than a level of the top surface 200a of the connection substrate 200. For example, the first molding layer 400 may include a resin material containing one or more of glass fiber and inorganic fillers, such as a prepreg, an ajinomoto build-up film (ABF), a flame retardant (FR-4), or bismaleimide triazine (BT).

The first logic chip 300 may be buried in the first molding layer 400 and the connection substrate 200, thereby being protected. In other words, the first molding layer 400 and the connection substrate 200 may protect the first logic chip 300 from external impacts. Thus, because the first logic chip 300 is not exposed to external impact, the semiconductor package 10 may increase in reliability and structural stability.

The first molding layer 400 may be provided thereon with a plurality of second conductive patterns 520 and a second dielectric pattern 510. The second dielectric pattern 510 may have a constant thickness that covers the top surface of the first molding layer 400. The second dielectric pattern 510 may be substantially the same as the first dielectric patterns 110 of the first redistribution substrate 100. For example, the second dielectric pattern 510 may include a photo-imageable dielectric (PID) or a dielectric material.

The plurality of second conductive patterns 520 may be positioned on the top surface of the first molding layer 400 and/or a top surface of the second dielectric pattern 510. The plurality of second conductive patterns 520 may penetrate a portion of the first molding layer 400 or a portion of the second dielectric pattern 510. The plurality of second conductive patterns 520 may be wiring lines that electrically connect the first logic chip 300 to a second logic chip 600 which will be discussed below and that electrically connect the connection substrate 200 to the second logic chip 600 which will be discussed below. Similar to the plurality of first conductive patterns 120, the plurality of second conductive patterns 520 may include a conductive material such as metal, for example, copper (Cu).

The second logic chip 600 may be provided on the second dielectric pattern 510. The second logic chip 600 may reside on and vertically overlap the first logic chip 300. The second logic chip 600 may have a size less than a size of the first redistribution substrate 100 and greater than a size of the opening OP of the connection substrate 200. For example, a size in the first direction D1 of the second logic chip 600 may be greater than a size in the first direction D1 of the first logic chip 300. For example, a width of the second logic chip 600 in the first direction D1 may be less than a width of the first redistribution substrate 100 in the first direction D1 and may be greater than a width of the opening OP of the connection substrate 200 in the first direction D1. The second logic chip 600 may include an application specific integrated circuit (ASIC) chip or an application processor (AP) chip. In some embodiments, the second logic chip 600 may include a central processing unit (CPU) or a graphic processing unit (GPU). The ASIC chip may include an application specific integrated circuit (ASIC).

The second logic chip 600 may include a second circuit layer 610 and a second semiconductor layer 620 on the second circuit layer 610. The second circuit layer 610 may include a plurality of second front pads 640, an integrated circuit, and a dielectric material. The plurality of second front pads 640 may be positioned on a bottom surface of the second circuit layer 610. The integrated circuit may be a logic circuit, and may be constituted by an electronic element such a transistor, a dielectric pattern, and wiring patterns. The dielectric material may cover the integrated circuit, and may expose the plurality of second front pads 640 on the bottom surface of the second circuit layer 610. For example, in some embodiments, the bottom surfaces of the plurality of second front pads 640 may be coplanar with the bottom surface of the second circuit layer 610. The second front pads 640 may be connected to chip terminals 650 which will be discussed below.

Since the second logic chip 600 is connected through the plurality of second front pads 640 to other components, in some embodiments it may be possible to omit components such as backside pads and through vias from the second logic chip 600 as compared with the plurality of backside pads 350 and the plurality of through vias 360 of the first logic chip 300. In the second logic chip 600, the bottom surface of the second circuit layer 610 including the integrated circuit thereon may be a second active surface of the second logic chip 600. A top surface of the second semiconductor layer 620 including no integrated circuit thereon may be a second inactive surface of the second logic chip 600. For example, a bottom surface 600b of the second logic chip 600 may correspond to the second active surface of the second logic chip 600, and a top surface 600a of the second logic chip 600 may correspond to the second inactive surface of the second logic chip 600. Since the second active surface of the second logic chip 600 is located at a lower level than a level of the second inactive surface of the second logic chip 600, the second logic chip 600 may be provided in a face-down position.

Since the first logic chip 300 is provided in a face-up position, and since the second logic chip 600 is provided in a face-down position, the first active surface of the first logic chip 300 may face the second active surface of the second logic chip 600. Therefore, the first logic chip 300 and the second logic chip 600 may be connected in a face-to-face manner.

The second logic chip 600 may be provided with a plurality of chip terminals 650 and an underfill layer 660 on the bottom surface 600b of the second logic chip 600. The plurality of chip terminals 650 may be positioned between the plurality of second front pads 640 of the second logic chip 600 and the plurality of second conductive patterns 520. For example, the plurality of chip terminals 650 may be positioned between corresponding ones of the plurality of second front pads 640 of the second logic chip 600 and corresponding ones of the plurality of second conductive patterns 520. For example, the plurality of chip terminals 650 may electrically connect the second logic chip 600 to the plurality of second conductive patterns 520. Thus, the second logic chip 600 may be electrically connected to the first logic chip 300 or may be electrically connected through the plurality of connection terminals 150 to the connection substrate 200. For example, the plurality of chip terminals 650 may include solder balls or solder bumps.

The underfill layer 660 may surround the plurality of chip terminals 650 and fill a space between the second logic chip 600 and the second dielectric pattern 510. A sidewall of the underfill layer 660 may be aligned with a sidewall of the second logic chip 600, but embodiments are not limited thereto. For example, in some embodiments, the sidewall of the underfill layer 660 may protrude in the second direction D2 more than the sidewall of the second logic chip 600. Since the underfill layer 660 prevents the plurality of chip terminals 650 from being outwardly exposed, the plurality of chip terminals 650 may improve in durability.

In some embodiments, the connection substrate 200 may be provided thereon with a second molding layer 700 that surrounds the sidewalls of the second logic chip 600. The second molding layer 700 may outwardly expose the top surface 600a of the second logic chip 600. For example, in some embodiments, a top surface of the second molding layer 700 may be coplanar with the top surface 600a of the second logic chip 600. The second molding layer 700 may have outer sidewalls aligned with sidewalls of the first redistribution substrate 100. The second molding layer 700 may include a different material from a material of the first molding layer 400. For example, the second molding layer 700 may include an epoxy molding compound (EMC). That is, in some embodiments, the second molding layer 700 may include an EMC material which is different from the resin material of the first molding layer 400.

The semiconductor package 10 according to some embodiments may include the first logic chip 300 and the second logic chip 600 that is positioned on and electrically connected to the first logic chip 300. The first logic chip 300 and the second logic chip 600 may be linked together to act as one system. For example, the first logic chip 300 and the second logic chip 600 may have a shape in which one logic chip is separated into pieces. The logic chip may thus become simple in terms of design structure and fabrication process. Therefore, the semiconductor package 10 may decrease in manufacturing cost. Moreover, since the first logic chip 300 is positioned in the opening OP of the connection substrate 200 and is direct-bonding mounted on the first redistribution substrate 100, the semiconductor package 10 may become smaller in size, as compared with the related art.

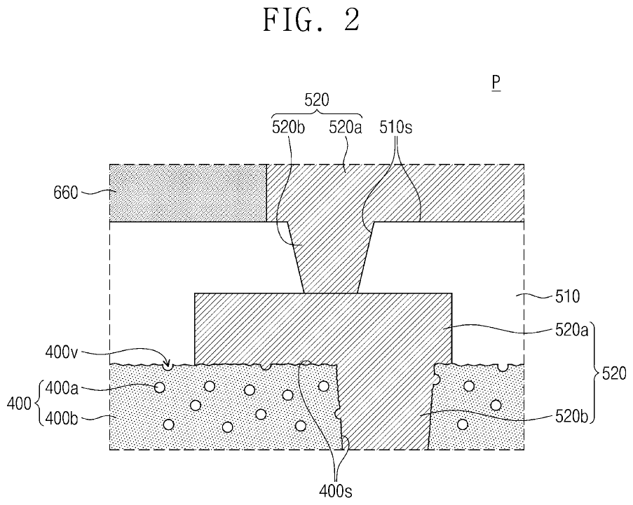

FIG. 2 illustrates an enlarged view of section P depicted in FIG. 1, showing a semiconductor package according to some embodiments.

Referring to FIG. 2, each of the plurality of second conductive patterns 520 may include a second line 520a and a second via 520b. The second via 520b may downwardly protrude from the second line 520a. For example, differently from the plurality of first conductive patterns 120 illustrated in FIG. 1, the plurality of second conductive patterns 520 may each have a T shape.

Lower ones of the plurality of second conductive patterns 520 may be positioned on the first molding layer 400. The second line 520a of the lower ones of the second conductive patterns 520 may be positioned on the top surface of the first molding layer 400, and the second via 520b of the lower ones of the second conductive patterns 520 may penetrate the first molding layer 400.

Upper ones of the second conductive patterns 520 may be positioned on the second dielectric pattern 510. The second line 520a of the upper ones of the second conductive patterns 520 may be positioned on the top surface of the second dielectric pattern 510, and the second via 520b of the upper ones of the second conductive patterns 520 may penetrate the second dielectric pattern 510. Thus, the second via 520b of the upper ones of the second conductive patterns 520 may be in contact with the second line 520a of corresponding lower ones of the second conductive patterns 520, such that the second conductive patterns 520 may be electrically connected to each other.

The second via 520b of each of the plurality of second conductive patterns 520 may be changed in accordance with a height of the second via 520b. For example, the width of the second via 520b may decrease with increasing distance from the second line 520a. In other words, the width of the second via 520b may increase in a vertical direction.

The first molding layer 400 may include a plurality of fillers 400a and a resin 400b. In some embodiments, the plurality of fillers 400a may be uniformly positioned in the resin 400b. The plurality of fillers 400a may be surrounded by the resin 400b. The first molding layer 400 may include the resin 400b in which the plurality of fillers 400a are contained. For example, the plurality of fillers 400a may include inorganic fillers such as silicon oxide (SiO₂) and aluminum oxide (Al₂O₃). Each of the plurality of fillers 400a may have a size of about 1 μm to about 5 μm. For example, in some embodiments, a diameter of each of the fillers 400a may be about 1 μm to about 5 μm. For example, the resin 400b may include a thermosetting resin such as epoxy resin or a thermoplastic resin such as polyimide.

The first molding layer 400 may have a surface 400s. The surface 400s of the first molding layer 400 may include the top surface of the first molding layer 400 and inner lateral surfaces of the first molding layer 400, which inner lateral surfaces are in contact with the second vias 520b of the lower ones of the second conductive patterns 520. The first molding layer 400 may include voids 400v on the surface 400s. The voids 400v may be formed by removal of the fillers 400a adjacent to the surface 400s of the first molding layer 400. Thus, the voids 400v may be filled with other components. For example, one or more of the voids 400v may be filled with the second dielectric pattern 510, and another one or more of the voids 400v may be filled with the second conductive pattern 520.

The surface 400s of the first molding layer 400 may have a first roughness. For example, the first molding layer 400 may have a roughness of about 1 μm to about 2 μm at the surface 400s on which the voids 400v are absent. Since the voids 400v are formed by removal of the fillers 400a, each of the voids 400v may have a size of about 1 μm to about 5 μm. Therefore, the first roughness may range from about 1 μm to about 5 μm.

The second dielectric pattern 510 may be in contact with a portion of the surface 400s of the first molding layer 400. The second dielectric pattern 510 may fill the voids 400v present on the surface 400s of the first molding layer 400 in contact with the second dielectric pattern 510.

The second dielectric pattern 510 may have a surface 510s. The surface 510s of the second dielectric pattern 510 may include the top surface of the second dielectric pattern 510 and inner lateral surfaces of the second dielectric pattern 510, which inner lateral surfaces are in contact with the second vias 520b of the upper ones of the second conductive patterns 520. The surface 510s of the second dielectric pattern 510 may have a second roughness. For example, the second roughness may range from about 1 nm to about 10 nm. The first roughness may be greater than the second roughness.

According to some embodiments, the surface 400s of the first molding layer 400 may have a roughness greater than the roughness of the surface 510s of the second dielectric pattern 510. Since the voids 400v are filled with the second conductive pattern 520 or the second dielectric pattern 510 in contact with the surface 400s of the first molding layer 400, and thus an anchoring structure may be formed on the surface 400s of the first molding layer 400. Thus, delamination may be prevented between the first molding layer 400 and the second dielectric pattern 510 and between the first molding layer 400 and the second conductive pattern 520 by the anchoring structure. Accordingly, the semiconductor package 10 may increase in reliability and structural stability.

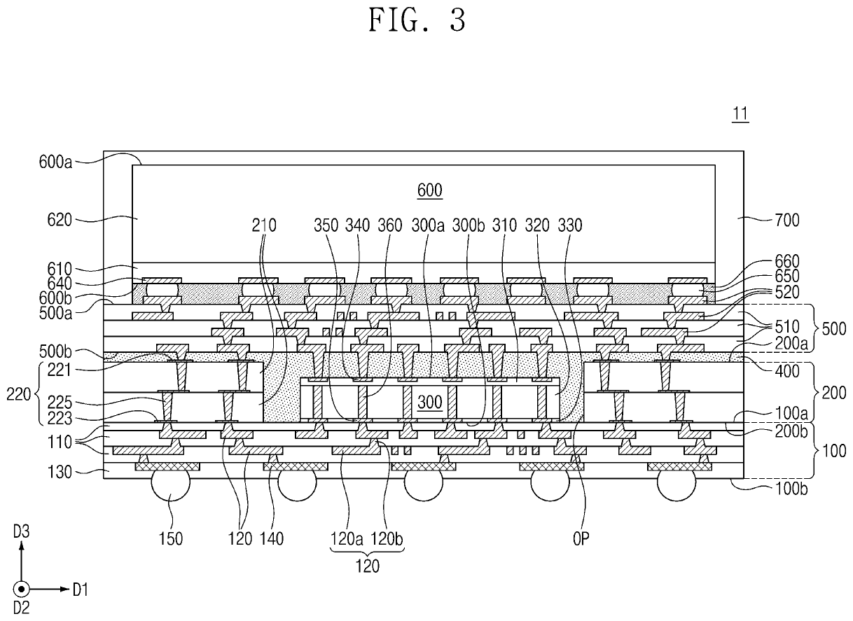

FIG. 3 illustrates a cross-sectional view showing a semiconductor package according to some embodiments.

In the embodiment illustrated in FIG. 3 and the description thereof below, a detailed description of technical features repetitive to those discussed above with reference to FIGS. 1 and 2 will be omitted to avoid redundancy and for conciseness, and a difference thereof mainly will be explained in detail.

Referring to FIG. 3, in a semiconductor package 11, a second redistribution substrate 500 may be provided on the connection substrate 200 and the first molding layer 400. The second redistribution substrate 500 may include a plurality of second dielectric patterns 510 and a plurality of second conductive patterns 520. The second redistribution substrate 500 may have a bottom surface 500b and a top surface 500a opposite to the bottom surface 500b. The top surface 500a of the second redistribution substrate 500 may be located at a higher level than a level of the bottom surface 500b of the second redistribution substrate 500.

The plurality of second dielectric patterns 510 may be stacked in the vertical direction (e.g., the third direction D3). In some embodiments, each of the plurality of second dielectric patterns 510 may have substantially the same thickness. A top surface of an uppermost one of the plurality of second dielectric patterns 510 may correspond to the top surface 500a of the second redistribution substrate 500. A bottom surface of a lowermost one of the plurality of second dielectric patterns 510 may correspond to the bottom surface 500b of the second redistribution substrate 500.

The plurality of second conductive patterns 520 may be positioned in the plurality of second dielectric patterns 510. For example, the plurality of second conductive patterns 520 may be positioned on the top surfaces of corresponding ones of the plurality of second dielectric patterns 510 or the top surface of the first molding layer 400. The plurality of second conductive patterns 520 may be wiring lines of the second redistribution substrate 500 or parts that connect the wiring lines to each other. For example, the plurality of second conductive patterns 520 may be components for horizontal redistribution in the second redistribution substrate 500.

Similar to the plurality of first conductive patterns 120, the plurality of second conductive patterns 520 may each have a damascene structure. As discussed with respect to FIG. 2, each of the plurality of second conductive patterns 520 may include a second line 520a and a second via 520b. The second via 520b may be a component for vertical connection between neighboring ones of the second lines 520a. In some embodiments, the second via 520b may be a component for connecting the second redistribution substrate 500 to the connection substrate 200 or the first logic chip 300. The second vias 520b may be coupled to the upper pads 221 of the connection substrate 200 or the front pads 340 of the first logic chip 300.

The second redistribution substrate 500 may be provided on a top surface 500a of the second redistribution substrate 500 with the second logic chip 600 and the second molding layer 700 that covers the second logic chip 600. The second molding layer 700 may have sidewalls aligned with sidewalls of the second redistribution substrate 500. Unlike the embodiment illustrated in FIG. 1, the second molding layer 700 in the embodiment illustrated in FIG. 3 may completely cover the second logic chip 600. For example, the second molding layer 700 may extend across the top surface 600a of the second logic chip 600. The second molding layer 700 may have a top surface located at a higher level than a level of the top surface 600a of the second logic chip 600, and the top surface 600a of the second logic chip 600 may not be outwardly exposed.

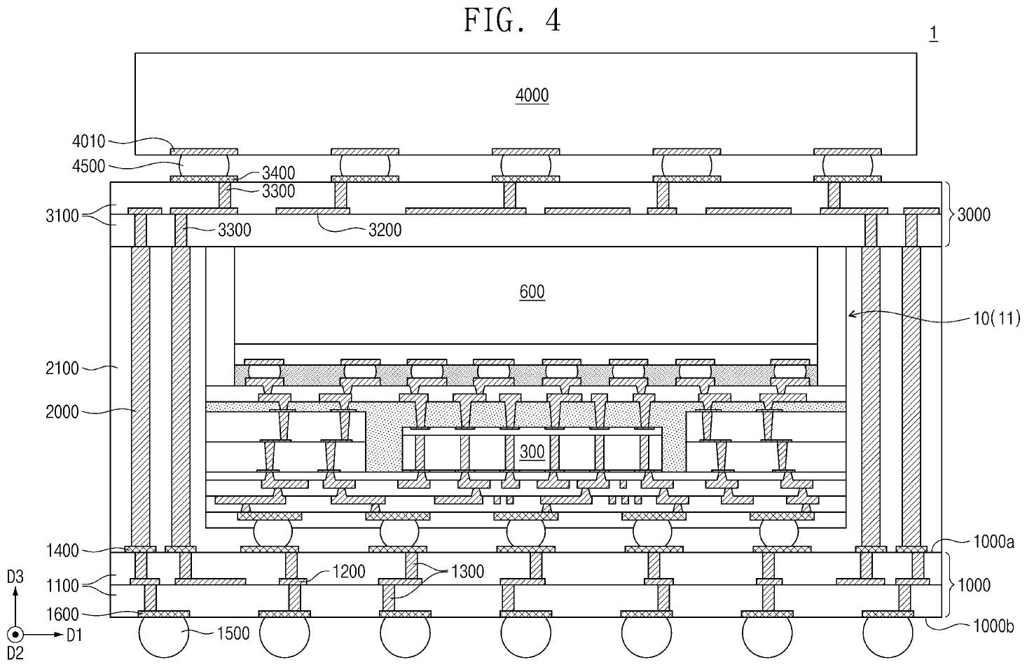

FIG. 4 illustrates a cross-sectional view showing a semiconductor package according to some embodiments.

In the embodiment illustrated in FIG. 4 and described below, a detailed description of technical features repetitive to those discussed above with reference to FIGS. 1 and 2 will be omitted to avoid redundancy and for conciseness, and a difference thereof mainly will be explained in detail.

Referring to FIG. 4, a lower redistribution substrate 1000 may be provided. The lower redistribution substrate 1000 may include a plurality of lower dielectric layers 1100, a plurality of lower vias 1300, a plurality of lower lines 1200, a plurality of upper pads 1400, and a plurality of lower pads 1600.

The plurality of lower dielectric layers 1100 may be stacked in the third direction D3. In some embodiments, each of the plurality of lower dielectric layers 1100 may have substantially the same thickness in the third direction D3. Two lower dielectric layers 1100 are illustrated in FIG. 4, but embodiments are not limited thereto. The number of the plurality of lower dielectric layers 1100 may be more than two, or in some embodiments, a single lower dielectric layer may be provided. For example, the plurality of lower dielectric layers 1100 may include a dielectric polymer or a photo-imageable dielectric (PID). The photo-imageable dielectric may include at least one selected from photosensitive polyimide, polybenzoxazole (PBO), phenolic polymers, and benzocyclobutene polymers. In some embodiments, the plurality of lower dielectric layers may include a dielectric material. The dielectric material may include silicon oxide (SiO), silicon nitride (SiN), silicon oxynitride (SiON), or a dielectric polymer.

The plurality of lower vias 1300 and the plurality of lower lines 1200 may be positioned in the plurality of lower dielectric layers 1100. The plurality of lower vias 1300 may penetrate the lower dielectric layers 1100. The plurality of lower lines 1200 may be positioned on top surfaces of corresponding lower ones of the plurality of lower dielectric layers 1100. The plurality of lower lines 1200 may electrically connect neighboring ones in the vertical direction D3 of the plurality of lower vias 1300 to each other. For example, the plurality of lower vias 1300 and the plurality of lower lines 1200 may be components for horizontal redistribution in the lower redistribution substrate 1000.

The plurality of upper pads 1400 may be positioned on the lower redistribution substrate 1000. The plurality of upper pads 1400 may have bottom surfaces in contact with a top surface 1000a of the lower redistribution substrate 1000. For example, the plurality of upper pads 1400 may protrude from the top surface 1000a of the lower redistribution substrate 1000. The plurality of upper pads 1400 may be connected to corresponding ones of the plurality of lower vias 1300 in a lower dielectric layer 1100 that is adjacent to the plurality of upper pads 1400.

The plurality of lower pads 1600 may be disposed below the lower redistribution substrate 1000. The plurality of lower pads 1600 may have bottom surfaces that are coplanar with a bottom surface 1000b of the lower redistribution substrate 1000. For example, the plurality of lower pads 1600 may be buried in the lowest one of the lower dielectric layers 1100. The plurality of lower pads 1600 may be connected to the lower vias 1300 in the lower dielectric layer 1100 that is adjacent to the plurality of lower pads 1600. Therefore, the plurality of lower pads 1600 may be electrically connected to the plurality of upper pads 1400 through the lower vias 1300 and the lower lines 1200.

For example, the lower vias 1300, the lower lines 1200, the upper pads 1400, and the lower pads 1600 of the lower redistribution substrate 1000 may include various metallic materials, such as one or more of copper (Cu), aluminum (Al), and nickel (Ni).

The lower redistribution substrate 1000 may be provided with a plurality of external connection terminals 1500 therebelow. The plurality of external connection terminals 1500 may be correspondingly positioned on bottom surfaces of the plurality of lower pads 1600. The lower redistribution substrate 1000 may be electrically connected through the plurality of external connection terminals 1500 to an external electronic apparatus or another semiconductor package. The plurality of external connection terminals 1500 may include, for example, solder balls or solder bumps.

The lower redistribution substrate 1000 may be provided thereon with a logic structure 10, a plurality of connection structures 2000, and a molding pattern 2100. The logic structure 10 may be substantially the same as one of the semiconductor packages 10 and 11 discussed in FIGS. 1 to 3. For example, the logic structure 10 may include a first logic chip 300 and a second logic chip 600 on the first logic chip 300, and the first logic chip 300 and the second logic chip 600 may be linked together to constitute one system, as discussed above.

The plurality of connection structures 2000 may be positioned on a lateral surface of the logic structure 10 and may be spaced apart from each other in the first direction D1. The plurality of connection structures 2000 may extend in the third direction D3. The plurality of connection structures 2000 may be correspondingly coupled to the plurality of upper pads 1400 of the lower redistribution substrate 1000. The connection structures 2000 may be components that electrically connect the lower redistribution substrate 1000 to an upper redistribution substrate 3000 which will be discussed below. The plurality of connection structures 2000 may be horizontally spaced apart from the logic structure 10, and when viewed in plan view, and the plurality of connection structures 2000 may not overlap the logic structure 10. When viewed in plan view, the plurality of connection structures 2000 may surround the logic structure 10. The connection structures 2000 may include metal, such as copper (Cu).

The molding pattern 2100 may surround horizontally the plurality of connection structures 2000 and the logic structure 10. For example, the plurality of connection structures 2000 and the logic structure 10 may be positioned between outer lateral surfaces of the molding pattern 2100 and corresponding side surfaces of the logic structure 10. A top surface of the molding pattern 2100 may be coplanar with top surfaces of the plurality of connection structures 2000 and a top surface of the logic structure 10. Embodiments, however, are not limited thereto, and in some embodiments, the top surface of the molding pattern 2100 may be located at a higher level than a level of the top surfaces of the plurality of connection structures 2000 and a level of the top surface of the logic structure 10. The molding pattern 2100 may fill a space between the logic structure 10 and the lower redistribution substrate 1000.

An upper redistribution substrate 3000 may be provided on the molding pattern 2100. The upper redistribution substrate 3000 may include a plurality of upper dielectric layers 3100, a plurality of upper vias 3300, a plurality of upper lines 3200, and a plurality of upper pads 3400. The upper redistribution substrate 3000 may be substantially the same as the lower redistribution substrate 1000. For example, the plurality of upper dielectric layers 3100 may be stacked in the third direction D3 and each of the plurality of upper dielectric layers 3100 may have substantially the same thickness. The plurality of upper vias 3300 and the plurality of upper lines 3200 may be positioned in the plurality of upper dielectric layers 3100, and may be provided for horizontal distribution in the upper redistribution substrate 3000. The plurality of upper pads 3400 may be positioned on a top surface of the upper redistribution substrate 3000.

A memory chip 4000 and a plurality of memory terminals 4500 may be provided on the upper redistribution substrate 3000. The memory chip 4000 may include a plurality of chip pads 4010. The plurality of chip pads 4010 may be buried in the memory chip 4000 and may be exposed on a bottom surface of the memory chip 4000. The plurality of chip pads 4010 may be correspondingly connected to the plurality of memory terminals 4500. For example, the memory chip 4000 may include a dynamic random access memory (DRAM).

The plurality of memory terminals 4500 may be positioned between the memory chip 4000 and the upper redistribution substrate 3000. The plurality of memory terminals 4500 may be correspondingly coupled to the plurality of chip pads 4010 and the plurality of upper pads 3400 of the upper redistribution substrate 3000. The plurality of memory terminals 4500 may electrically connect the memory chip 4000 to the upper redistribution substrate 3000. For example, the plurality of memory terminals 4500 may include solder balls or solder bumps.

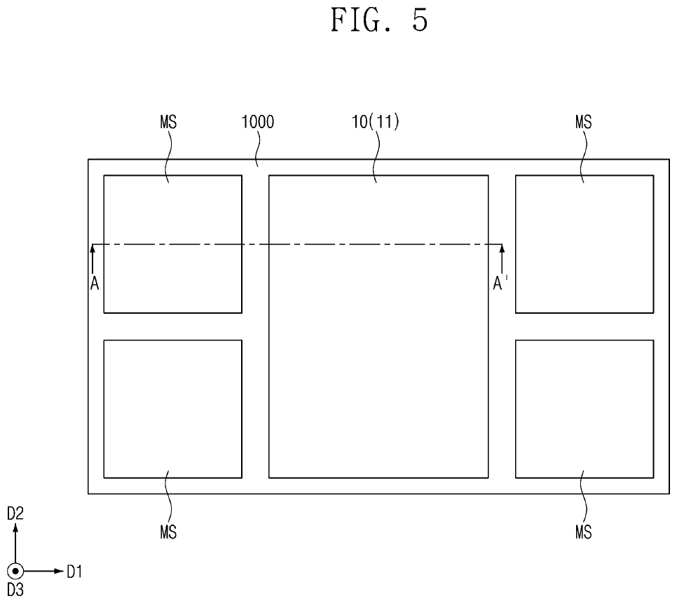

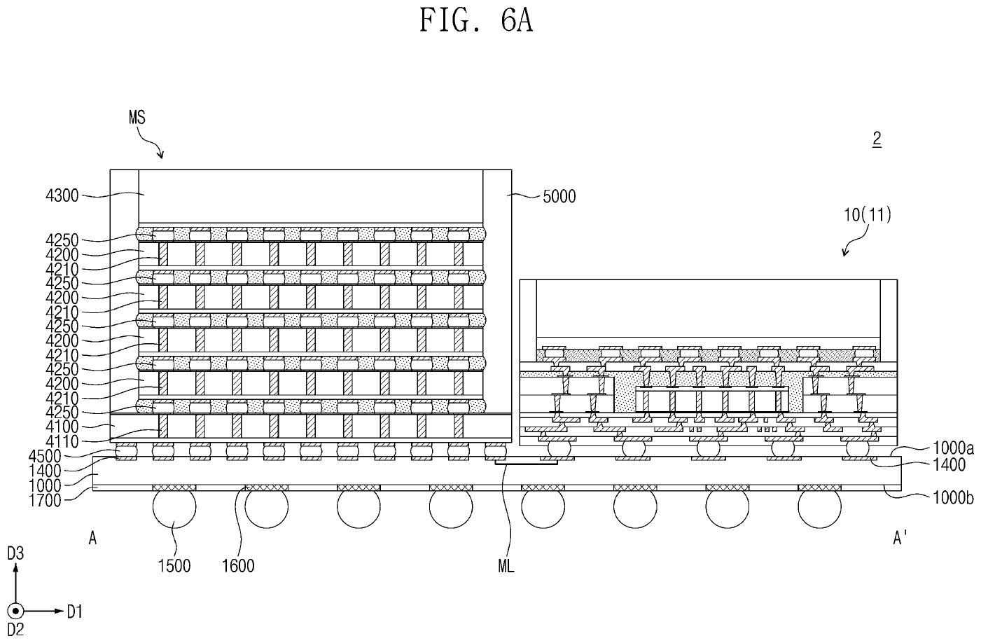

FIG. 5 illustrates a plan view showing a semiconductor package according to some embodiments. FIGS. 6A and 6B illustrate cross-sectional views taken along line A-A′ of FIG. 5, showing a semiconductor package according to some embodiments.

In the embodiment illustrated in FIGS. 5-6B and described below, a detailed description of technical features repetitive to those discussed above with reference to FIGS. 1 to 4 will be omitted to avoid redundancy and for conciseness, and a difference thereof mainly will be explained in detail.

Referring to FIGS. 5 and 6A, a semiconductor package 2 according to some embodiments may include a lower redistribution substrate 1000, and may also include a plurality of memory structures MS and a logic structure 10 on the lower redistribution substrate 1000. When viewed in plan view, the memory structures MS and the logic structure 10 may overlap the lower redistribution substrate 1000. The memory structures MS may be positioned on opposite lateral surfaces of the logic structure 10, and the memory structures MS and the logic structure 10 may be spaced apart from each other. For example, the logic structure 10 may be positioned between the memory structures MS that neighbor each other in the first direction D1. The memory structures MS may be spaced apart from each other in the first direction D1 and/or the second direction D2.

The lower redistribution substrate 1000 may include the upper pads 1400, the lower pads 1600, and a metal line ML. The upper pads 1400 may be positioned on a top surface 1000a of the lower redistribution substrate 1000 and may be spaced apart from each other. The lower pads 1600 may be positioned on a bottom surface 1000b of the lower redistribution substrate 1000 and may be spaced apart from each other. The metal line ML may electrically connect the logic structure 10 to the memory structures MS. For example, in some embodiments, the lower redistribution substrate 1000 may be a printed circuit board (PCB).

The lower redistribution substrate 1000 may be provided on a bottom surface 1000b of the lower redistribution substrate 1000 with the external connection terminals 1500 and a protection layer 1700. The protection layer 1700 may cover the bottom surface 1000b of the lower redistribution substrate 1000, while surrounding lateral surfaces of the lower pads 1600. For example, the protection layer 1700 may outwardly expose the lower pads 1600. The plurality of external connection terminals 1500 may be correspondingly positioned on bottom surfaces of the plurality of lower pads 1600. The external connection terminals 1500 may be coupled to the lower pads 1600 and electrically connected through the lower pads 1600 to the upper pads 1400. For example, the external connection terminals 1500 may each be an alloy that includes at least one selected from tin (Sn), silver (Ag), copper (Cu), nickel (Ni), bismuth (Bi), indium (In), antimony (Sb), and cerium (Ce).

The logic structure 10 may be mounted on the lower redistribution substrate 1000. The logic structure 10 may be substantially the same as one of the semiconductor packages 10 and 11 discussed in FIGS. 1 to 3. The logic structure 10 may be coupled to ones of the plurality of upper pads 1400, which vertically overlap the logic structure 10, of the lower redistribution substrate 1000 and electrically connected to the lower redistribution substrate 1000. For example, in some embodiments, the logic structure 10 may be coupled to only the ones of the plurality of upper pads 1400 which vertically overlap the logic structure in the vertical direction D3.

The memory structure MS may be mounted on the lower redistribution substrate 1000, while being spaced apart in the first direction D1 from the logic structure 10. The memory structure MS may have a chip stack structure. The memory structure MS may include a base chip 4100, a plurality of lower memory chips 4200, and an upper memory chip 4300. The base chip 4100, the plurality of lower memory chips 4200, and the upper memory chip 4300 may be sequentially stacked in the third direction D3.

A width of the base chip 4100 may be greater than a width of each of the lower memory chips 4200 and greater than a width of the upper memory chip 4300. The width of each of the lower memory chips 4200 may be substantially the same as the width of the upper memory chip 4300. In some embodiments, the base chip 4100 may include a logic chip, a controller chip, or a buffer chip, etc. In some embodiments, the lower memory chips 4200 and the upper memory chip 4300 may be, for example, semiconductor chips whose types are different from the type of the base chip 4100. In some embodiments, the lower memory chips 4200 and the upper memory chip 4300 may be, for example, memory chips. For example, the memory chip may be a dynamic random access memory (DRAM).

The base chip 4100 may include a plurality of first upper chip pads, a plurality of first lower chip pads, and a plurality of first through electrodes 4110. The first upper chip pads may be positioned on a top surface of the base chip 4100, and the first lower chip pads may be positioned on a bottom surface of the base chip 4100. The first through electrodes 4110 may be positioned in the base chip 4100, and may penetrate in the third direction D3 through the base chip 4100. The first through electrodes 4110 may electrically connect the first upper chip pads to the first lower chip pads. For example, the first upper chip pads and the first lower chip pads may include a metallic material, such as one or more of copper (Cu), aluminum (Al), and nickel (Ni), and the first through electrodes 4110 may include a metallic material, such as one or more of copper (Cu), titanium (Ti), tungsten (W), and any combination thereof.

The plurality of lower memory chips 4200 may be stacked in the third direction D3 on the base chip 4100. Each of the plurality of lower memory chips 4200 may include a plurality of second upper chip pads, a plurality of second lower chip pads, and a plurality of second through electrodes 4210. The second lower chip pads of a lower memory chip 4200 may be positioned on a bottom surface of the lower memory chip 4200, and the second upper chip pads of a lower memory chip 4200 may be positioned on a top surface of the lower memory chip 4200. For example, the second upper chip pads and the second lower chip pads may include a metallic material, such as one or more of copper (Cu), aluminum (Al), and nickel (Ni).

The second through electrodes 4210 of a lower memory chip 4200 may be positioned in the lower memory chip 4200, and may penetrate in the third direction D3 through the lower memory chip 4200. The plurality of second through electrodes 4210 may be spaced apart from each other in a horizontal direction. The second through electrodes 4210 of a lower memory chip 4200 may be correspondingly coupled to the second upper chip pads and the second lower chip pads of the lower memory chip 4200. For example, the second through electrodes 4210 may include a metallic material, such as one or more of copper (Cu), titanium (Ti), tungsten (W), and any combination thereof.

The upper memory chip 4300 may be disposed on an uppermost one of the plurality of lower memory chips 4200. The upper memory chip 4300 may be a semiconductor chip positioned at top of the memory structure MS. The upper memory chip 4300 may be provided with a plurality of third lower chip pads on a bottom surface of the upper memory chip 4300.

A plurality of chip connection terminals 4250 may be provided between adjacent ones of the base chip 4100, the lower memory chips 4200, and the upper memory chip 4300, as illustrated in FIG. 6A. The plurality of chip connection terminals 4250 may be correspondingly disposed between the first upper chip pads, the second upper chip pads, the second lower chip pads, and the third lower chip pads. The plurality of chip connection terminals 4250 may electrically connect the base chip, the lower memory chip 4200, and the upper memory chip 4300.

On the base chip 4100, a chip stack molding layer 5000 may surround the upper memory chip 4300 and the plurality of lower memory chips 4200. A lateral surface of the chip stack molding layer 5000 may be aligned with a lateral surface of the base chip 4100. The chip stack molding layer 5000 may expose a top surface of the upper memory chip 4300. In some embodiments, a top surface of the chip stack molding layer 5000 may be coplanar with the top surface of the upper memory chip 4300. In some embodiments, the chip stack molding layer 5000 may cover the top surface of the upper memory chip 4300. In other words, in some embodiments, the chip stack molding layer 5000 may extend across the top surface of the upper memory chip 4300 to cover the upper memory chip 4300. For example, the chip stack molding layer 5000 may include an epoxy molding compound (EMC).

In some embodiments, the memory structures MS may include high bandwidth memory (HBM) chips. The number of the lower memory chips 4200 and the upper memory chip 4300 stacked on the base chip 4100 in each of the memory structures MS may be variously changed, and an increase in the number of the lower memory chips 4200 and the upper memory chip 4300 may lead to an increase in storage capacity.

Referring to FIGS. 5 and 6B, in some embodiments, the lower redistribution substrate 1000 may include the lower dielectric layers 1100 stacked in the third direction D3, and a bridge chip 6000 may be provided in an uppermost one of the lower dielectric layers 1100. When viewed in plan view, the bridge chip 6000 may overlap a portion of the memory structure MS and a portion of the logic structure 10.

The bridge chip 6000 may include a bridge base layer 6200 and a bridge wiring layer 6100. The bridge base layer 6200 may include a semiconductor substrate.

For example, the bridge base layer 6200 may be a semiconductor substrate, such as a semiconductor wafer. The bridge base layer 6200 may be a silicon (Si) substrate, a silicon-on-insulator (SOI) substrate, a germanium (Ge) substrate, a germanium-on-insulator (GOI) substrate, a silicon-germanium (SiGe) substrate, a III-V group semiconductor substrate, or an epitaxial film substrate obtained by performing selective epitaxial growth (SEG). The bridge base layer 6200 may include, for example, at least one selected from silicon (Si), germanium (Ge), silicon germanium (SiGe), gallium arsenic (GaAs), indium gallium arsenic (InGaAs), aluminum gallium arsenic (AlGaAs), and a mixture thereof.

The bridge wiring layer 6100 may be disposed on a top surface of the bridge base layer 6200. For example, the bridge wiring layer 6100 may include a bridge dielectric pattern and a bridge wiring pattern 6300 that are formed on the top surface of the bridge base layer 6200. In some embodiments, the bridge wiring layer 6100 may further include a circuit pattern or a protection layer.

The bridge dielectric pattern may include a dielectric material such as silicon oxide (SiO), silicon nitride (SiN), silicon oxynitride (SiON), silicon carbonitride (SiCN), or dielectric polymers, and may surround the bridge wiring pattern 6300. The bridge wiring pattern 6300 may be provided in the bridge dielectric

pattern. The bridge wiring pattern 6300 may be a component for electrical connection between the memory structure MS and the logic structure 10. The bridge wiring pattern 6300 may include a conductive material. For example, the bridge wiring pattern 6300 may include copper (Cu) or aluminum (Al).

The bridge chip 6000 may include a plurality of bridge pads 6400. The bridge pads 6400 may be positioned on a top surface of the bridge wiring layer 6100. Each of the plurality of bridge pads 6400 may have different sizes. The bridge pads 6400 may be exposed on the top surface of the bridge wiring layer 6100. Some of the plurality of bridge pads 6400 may be coupled to the memory structure MS, and remaining ones of the plurality of bridge pads 6400 may be coupled to the logic structure 10. Therefore, the memory structure MS and the logic structure 10 may be electrically connected through the bridge chip 6000.

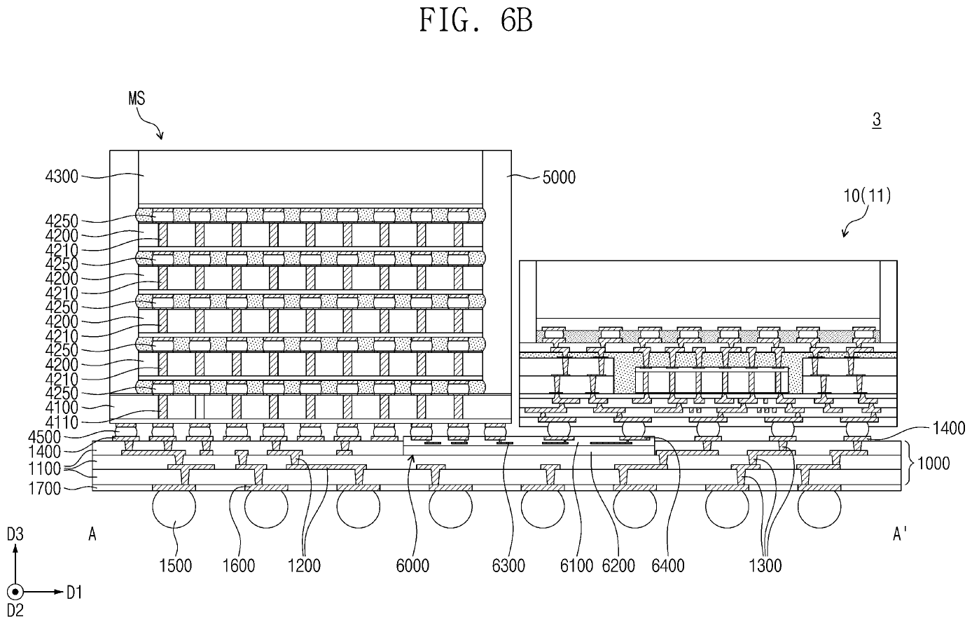

FIGS. 7 to 12 illustrate cross-sectional views showing a method of fabricating a semiconductor package according to some embodiments. For example, in some embodiments, the method of fabricating may be applied for fabricating one of the semiconductor packages 10 or 11 described above.

Referring to FIG. 7, a connection substrate 200 may be formed. The connection substrate 200 may include the base layers 210 and the conductive member 220. The conductive member 220 may include the upper pads 221, the lower pads 223, and the connection vias 225. A lower one of the base layers 210 and the conductive member 220 therein may be formed, and then an upper one of the base layers 210 and the conductive member 220 therein may be subsequently formed.

The opening OP may be formed in the connection substrate 200. A portion of the connection substrate 200 may be removed to form the opening OP. The opening OP may penetrate from the top surface 200a of the connection substrate 200 to the bottom surface 200b of the connection substrate 200. The opening OP may be formed by, for example, an etching process such as drilling, laser ablation, or laser cutting.

After the formation of the opening OP in the connection substrate 200, an adhesive layer 810 may be formed on the bottom surface 200b of the connection substrate 200. The adhesive layer 810 may close one side of the opening OP, while covering the bottom surface 200b of the connection substrate 200. For example, the adhesive layer 810 may include a photo-imageable dielectric (PID). The photo-imageable dielectric may include at least one selected from photosensitive polyimide, polybenzoxazole (PBO), phenolic polymers, and benzocyclobutene polymers.

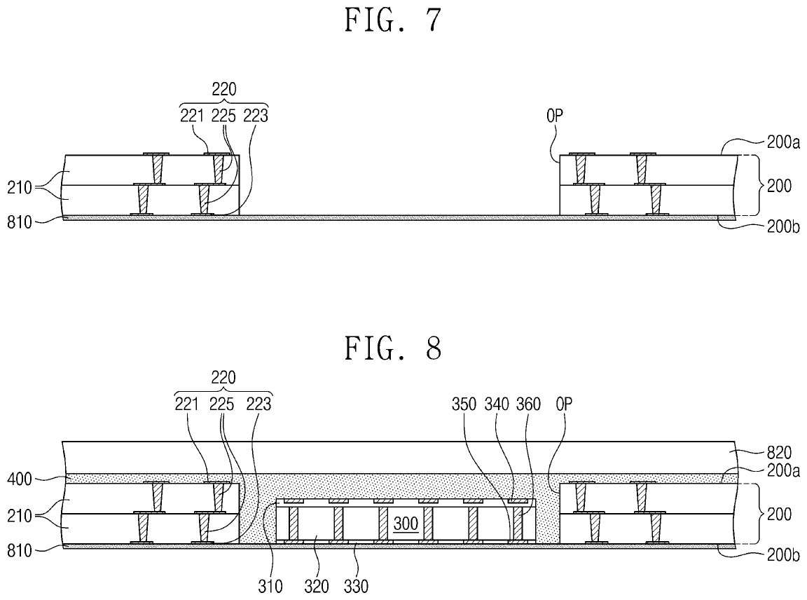

Referring to FIG. 8, the first logic chip 300 may be provided in the opening OP of the connection substrate 200. The first logic chip 300 may fill a portion of the opening OP. The first logic chip 300 may include the first circuit layer 310, the first protection layer 330, and the first semiconductor layer 320 between the first circuit layer 310 and the first protection layer 330. The first logic chip 300 may be attached to the adhesive layer 810. In this case, the first logic chip 300 may be attached to cause the first protection layer 330 to face the adhesive layer 810. For example, the first protection layer 330 of the first logic chip 300 may be in contact with the adhesive layer 810.

The first molding layer 400 may be formed to cover the connection substrate 200 and the first logic chip 300. The first molding layer 400 may fill an unoccupied portion of the opening OP. The first molding layer 400 may extend into a gap between the connection substrate 200 and the first logic chip 300. For example, a portion of the first molding layer 400 may be formed between the connection substrate 200 and the first logic chip 300. The formation of the first molding layer 400 may include providing a molding member between the connection substrate 200 and the first logic chip 300, and curing the molding member.

After the formation of the first molding layer 400, a first carrier substrate 820 may be formed on the first molding layer 400. The first carrier substrate 820 may cover a top surface of the first molding layer 400. For example, the first carrier substrate 820 may be a dielectric substrate including glass or polymer or a conductive substrate including metal. The first carrier substrate 820 may be attached through an adhesive member to the first molding layer 400.

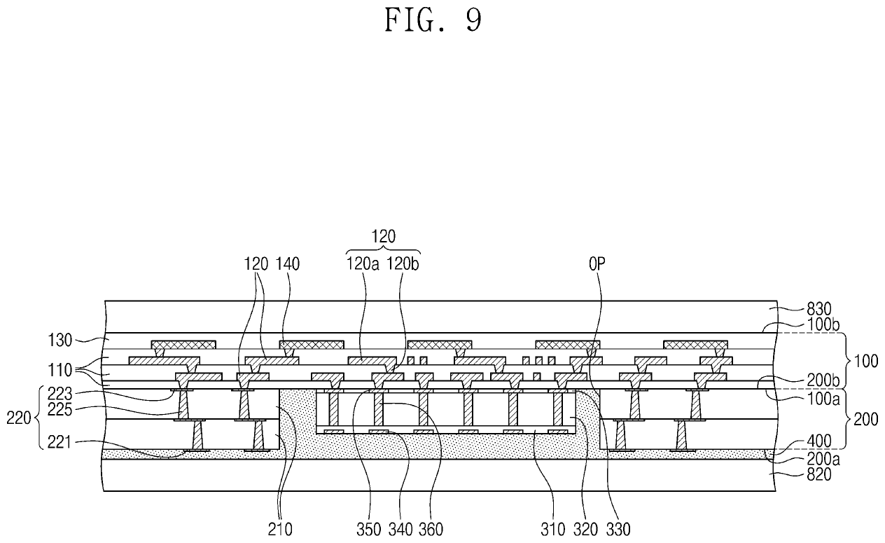

Referring to FIG. 9, the first carrier substrate 820 may be overturned. For example, the first carrier substrate 820 may be placed at a lower position, and the connection substrate 200 may be placed at an upper position. Thus, the bottom surface 200b of the connection substrate 200 may be located at a higher level than a level of the top surface 200a of the connection substrate 200. The adhesive layer 810 may be removed. The removal of the adhesive layer 810 may expose the bottom surface 200b of the connection substrate 200, the first protection layer 330 of the first logic chip 300, and a portion of the first molding layer 400.

After the removal of the adhesive layer 810, the first redistribution substrate 100 may be formed on the bottom surface 200b of the connection substrate 200. The formation of the first redistribution substrate 100 may include forming a dielectric layer on the connection substrate 200 and the first logic chip 300, patterning the dielectric layer to form the first dielectric pattern 110, forming a conductive layer on the first dielectric pattern 110, and patterning the conductive layer to form the first conductive pattern 120. The process of forming the dielectric layer to patterning the conductive layer may be repeated. Therefore, the plurality of first dielectric patterns 110 may be formed stacked in the vertical direction, and the plurality of first conductive patterns 120 may be formed in the first dielectric patterns 110.

The connection terminal pads 140 and the substrate protection layer 130 may be formed, and a second carrier substrate 830 may be formed on the substrate protection layer 130. The substrate protection layer 130 may cover the connection terminal pads 140 and the first dielectric patterns 110. The second carrier substrate 830 may include substantially the same material as a material of the first carrier substrate 820.

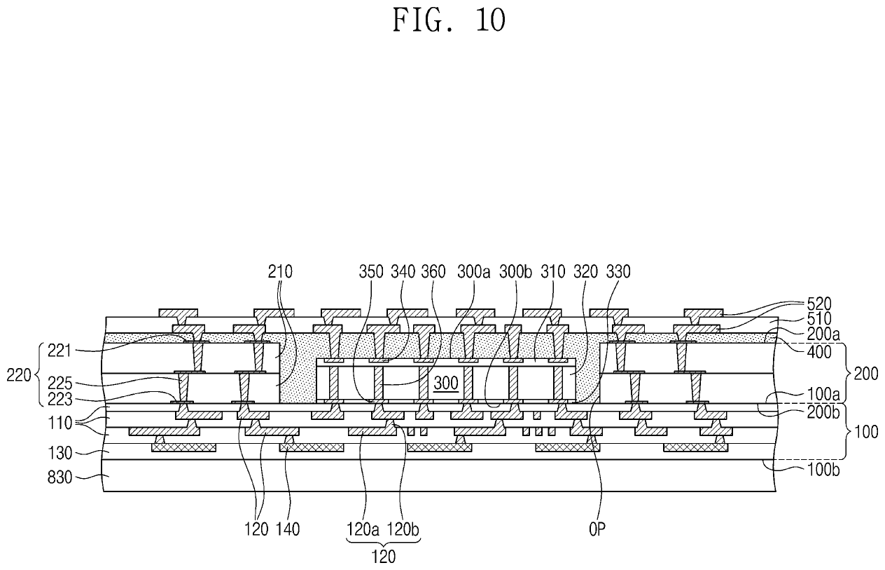

Referring to FIG. 10, the second carrier substrate 830 may be overturned. For example, the second carrier substrate 830 may be placed at a lower position, and the first carrier substrate 820 may be placed at an upper position. Thus, the top surface 200a of the connection substrate 200 may be located at a higher level than a level of the bottom surface 200b of the connection substrate 200. The first carrier substrate 820 may be removed. The removal of the first carrier substrate 820 may expose the first molding layer 400.

The second conductive pattern 520 may be formed on the first molding layer 400. The formation of the second conductive pattern 520 may include removing a portion of the first molding layer 400, forming a conductive layer to fill a removed portion of the first molding layer 400, and patterning the conductive layer to form a second conductive pattern 520. The second conductive pattern 520 may be coupled to the upper pads 221 of the connection substrate 200 or to the front pads 340 of the first logic chip 300.

The second dielectric pattern 510 and another second conductive pattern 520 may be formed on the first molding layer 400. The formation of the second dielectric pattern 510 and the second conductive pattern 520 may be substantially the same as the formation of the first dielectric pattern 110 and the first conductive pattern 120 of the first redistribution substrate 100. For example, the formation of the second dielectric pattern 510 may include forming a dielectric layer that covers the first molding layer 400 and patterning the dielectric layer. The formation of the second conductive pattern 520 may include forming a conductive layer on the second dielectric pattern 510 and patterning the conductive layer.

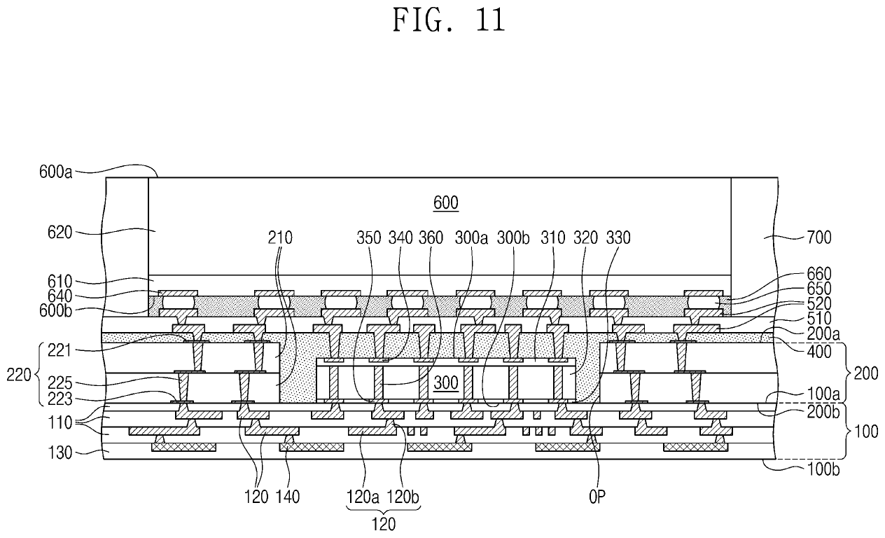

Referring to FIG. 11, the second logic chip 600 may be provided on the second dielectric pattern 510. The second logic chip 600 may include the second circuit layer 610 and the second semiconductor layer 620, and the second circuit layer 610 may be positioned to face the second dielectric pattern 510. The chip terminals 650 may be correspondingly positioned on uppermost ones of the second conductive patterns 520. After, a reflow process may be employed to bond the second conductive patterns 520 and the chip terminals 650 to each other. Thus, the second logic chip 600 may be mounted on the connection substrate 200 and the first logic chip 300.

The second molding layer 700 may be formed to cover the second logic chip 600. The formation of the second molding layer 700 may include providing a molding member to cover the second logic chip 600, curing the molding member, and grinding the cured molding member. The molding member may be ground such that the second molding layer 700 may be positioned only on a lateral surface of the second logic chip 600, and may expose the top surface 600a of the second logic chip 600. For example, a top surface of the second molding layer 700 may be coplanar with the top surface 600a of the second logic chip 600. In some embodiments, the grinding process may be omitted to form the semiconductor package 11 illustrated in FIG. 3.

After the formation of the second molding layer 700, the second carrier substrate 830 may be removed. The removal of the second carrier substrate 830 may expose the substrate protection layer 130.

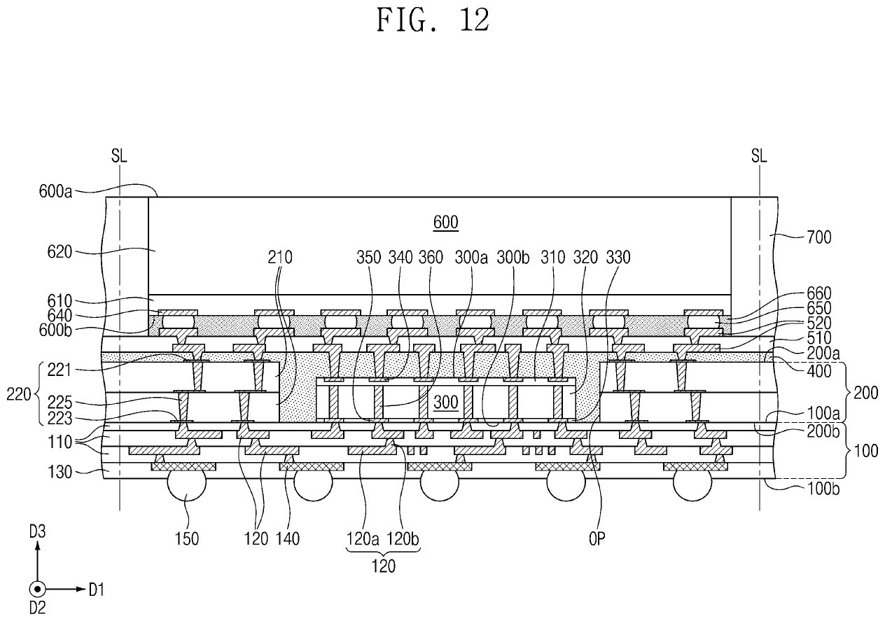

Referring to FIG. 12, the connection terminals 150 may be formed on the connection terminal pads 140. The formation of the connection terminals 150 may include patterning the substrate protection layer 130 to expose the connection terminal pads 140, and attaching the connection terminals 150 on the exposed connection terminal pads 140.

After the formation of the connection terminals 150, a sawing process may be performed along sawing lines SL. The sawing process may dice the first redistribution substrate 100, the connection substrate 200, the first molding layer 400, and the second molding layer 700. Thus, the first redistribution substrate 100, the connection substrate 200, the first molding layer 400, and the second molding layer 700 may each be divided into a plurality of pieces. Accordingly, it may be possible to form a plurality of semiconductor packages 10 discussed in FIGS. 1 and 2, or a plurality of semiconductor packages 11 discussed in FIG. 3.

A semiconductor package according to various embodiments may include the first logic chip and the second logic chip on the first logic chip. The first logic chip and the second logic chip may be linked together to act as one system. A logic chip may thus become simple in terms of design structure and fabrication process. Accordingly, the semiconductor package according to various embodiments may decrease in manufacturing cost. In addition, the first logic chip may be positioned in the opening of the connection substrate, and a direct bonding may be used to mount the first logic chip on the first redistribution substrate, with the result that the semiconductor package may become small in size.

Although various embodiments have been described in connection with the accompanying drawings, it will be understood to those skilled in the art that various changes and modifications may be made without departing from the technical spirit and scope of the present disclosure. It therefore will be understood that the embodiments described above are just illustrative but not limitative in all aspects, and any changes or modifications thereof are encompassed in the appended claims.

What is claimed is:

1. A semiconductor package comprising:
a lower redistribution substrate;
a logic structure on the lower redistribution substrate;
a plurality of connection terminals between the lower redistribution substrate and the logic structure;
a plurality of connection structures on the lower redistribution substrate, the plurality of connection structures surrounding the logic structure in plan view; and
a plurality of external connection terminals below the lower redistribution substrate,
wherein the logic structure includes:
a first redistribution substrate;
a connection substrate on the first redistribution substrate, the connection substrate having an opening in the connection substrate;
a first logic chip on the first redistribution substrate and in the opening in the connection substrate; and
a second logic chip on the connection substrate and the first logic chip,
wherein a first active surface of the first logic chip faces a second active surface of the second logic chip.

2. The semiconductor package of claim 1, wherein a size in a first direction of the second logic chip is greater than a size in the first direction of the first logic chip.

3. The semiconductor package of claim 1, wherein the first logic chip includes a plurality of through vias that electrically connect the first active surface of the first logic chip to a first inactive surface of the first logic chip that is opposite to the first active surface.

4. The semiconductor package of claim 1, further comprising:
an upper redistribution substrate on the plurality of connection structures and on the logic structure; and
a memory chip on the upper redistribution substrate,
wherein the plurality of connection structures electrically connect the lower redistribution substrate to the upper redistribution substrate.

5. A semiconductor package comprising:
a first redistribution substrate;
a connection substrate on the first redistribution substrate, the connection substrate having an opening in the connection substrate;
a first logic chip on the first redistribution substrate and in the opening of the connection substrate;
a first molding layer that covers the connection substrate and the first logic chip;
a dielectric pattern on the first molding layer; and
a second logic chip on the dielectric pattern,
wherein the first molding layer extends into a gap between the connection substrate and the first logic chip and includes a resin material containing a filler.

6. The semiconductor package of claim 5, wherein a roughness of a surface of the first molding layer is greater than a roughness of a surface of the dielectric pattern.

7. The semiconductor package of claim 5, further comprising a connection terminal between the dielectric pattern and the second logic chip.

8. The semiconductor package of claim 5, wherein:
a first active surface of the first logic chip faces a second active surface of the second logic chip, and
a size in a first direction of the first logic chip is less than a size in the first direction of the second logic chip.

9. The semiconductor package of claim 5, further comprising a second molding layer that covers the second logic chip,
wherein the second molding layer includes a material different from the resin material of the first molding layer.

10. The semiconductor package of claim 5, wherein a diameter of the filler is in a range of about 1 μm to about 5 μm.

11. A semiconductor package comprising:
a first redistribution substrate that includes a redistribution line and a redistribution via;
a connection substrate on the first redistribution substrate, the connection substrate having an opening that includes a connection via;
a first logic chip in the opening in the connection substrate, the first logic chip including a through via; and
a second logic chip on the first logic chip,
wherein a width of the redistribution via decreases with an increasing distance from a bottom surface of the first redistribution substrate,
wherein a width of the connection via increases with the increasing distance from the bottom surface of the first redistribution substrate, and
wherein a size in a first direction of the first logic chip is less than a size in the first direction of the second logic chip.

12. The semiconductor package of claim 11, wherein the first logic chip and the second logic chip are linked together to constitute one system.

13. The semiconductor package of claim 11, further comprising:
a molding layer that covers the connection substrate and the first logic chip and extends into a gap between the connection substrate and the first logic chip; and
a second redistribution substrate between the molding layer and the second logic chip.

14. The semiconductor package of claim 13, wherein the second redistribution substrate includes a dielectric pattern and a conductive pattern,
wherein a roughness of a surface of the molding layer is greater than a roughness of a surface of the dielectric pattern.

15. The semiconductor package of claim 13, wherein the molding layer includes a resin containing a filler,
wherein a diameter of the filler is in a range of about 1 μm to about 5 μm.

16. The semiconductor package of claim 11, wherein each of the first logic chip and the second logic chip includes an active surface and an inactive surface opposite to the active surface,
wherein the active surface of the first logic chip faces the active surface of the second logic chip.

17. The semiconductor package of claim 16, wherein the active surface of the second logic chip is at a level higher than a level of a top surface of the connection substrate.

18. The semiconductor package of claim 16, wherein the inactive surface of the first logic chip is in contact with a top surface of the first redistribution substrate.

19. The semiconductor package of claim 11, further comprising:
a package substrate below the first redistribution substrate; and
a memory structure on the package substrate,
wherein the memory structure is horizontally spaced apart from the first logic chip and the second logic chip.

20. The semiconductor package of claim 19, wherein the memory structure includes a plurality of memory chips that are stacked in a vertical direction.
